(19) United States
(12) Patent Application Publication
(10) Pub. No.: US 2024/0297134 A1
(43) Pub. Date: Sep. 5, 2024

(54) ELECTRONIC PACKAGE

(71) Applicant: Skyworks Solutions, Inc., Irvine, CA (US)

(72) Inventors: Suresh Babu Yeruva, Marion, IA (US); Dae Keun Park, Irvine, CA (US); Chien Jen Wang, Taoyuan City (TW); Ki Wook Lee, Irvine, CA (US)

(21) Appl. No.: 18/593,660

(22) Filed: Mar. 1, 2024

Related U.S. Application Data
(60) Provisional application No. 63/449,504, filed on Mar. 2, 2023.
(60) Provisional application No. 63/449,512, filed on Mar. 2, 2023.

(51) Int. Cl. H01L 23/00; H01L 25/10

(52) U.S. Cl. CPC H01L 24/10; H01L 24/16; H01L 24/32; H01L 24/73; H01L 25/105; H01L 24/81; H01L 2224/10175; H01L 2224/1607; H01L 2224/16227; H01L 2224/16238; H01L 2224/32225; H01L 2224/73204; H01L 2224/81007; H01L 2224/81815; H01L 2924/3841

(57) ABSTRACT

An electronic package and method of manufacture are provided. The electronic package has a substrate panel, an electronic module mounted to a surface of the substrate panel, and a plurality of electrically conductive contact pads arranged on the surface of the substrate panel. The electronic module includes a group of electrically conductive nodes. A predetermined one of the plurality of electrically conductive contact pads is associated with the group of electrically conductive nodes. The group of electrically conductive nodes is coupled to a corresponding group of spatially distinct fusion areas of the predetermined electrically conductive contact pad by corresponding intermediate solder portions. A solder masking arrangement extends over a part of the surface of the substrate panel. The masking arrangement is arranged over the predetermined electrically conductive contact pad and configured to at least partially define the group of spatially distinct fusion areas.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The present disclosure relates to an electronic package. The present disclosure also relates to an electronic device comprising an electronic package. The present disclosure also relates to a method of manufacturing an electronic package.

### Description of the Related Technology

Conventional electronic packages have a substrate panel and an electronic module mounted to the substrate panel. Optimum or efficient operation of certain electronic modules may be facilitated by two or more electrically conductive nodes of the electronic module being coupled to a common electrically conductive interface on the substrate panel. Coupling to the common electrically conductive interface is achieved by use of portions of solder fused between the two or more electrically conductive nodes and the common electrically conductive interface.

### SUMMARY

According to one embodiment there is provided an electronic package including a substrate panel, an electronic module mounted to a surface of the substrate panel, and a plurality of electrically conductive contact pads arranged on the surface of the substrate panel. The electronic module includes a group of electrically conductive nodes. A predetermined one of the plurality of electrically conductive contact pads associated with the group of electrically conductive nodes, the group of electrically conductive nodes coupled to a corresponding group of spatially distinct fusion areas of the predetermined electrically conductive contact pad by corresponding intermediate solder portions. A solder masking arrangement extending over a part of the surface of the substrate panel, the masking arrangement arranged over the predetermined electrically conductive contact pad and configured to at least partially define the group of spatially distinct fusion areas.

In one example the group of spatially distinct fusion areas is formed of two spatially distinct fusion areas.

In one example which the masking arrangement is configured to partially surround or enclose the group of spatially distinct fusion areas.

In one example the masking arrangement is configured to fully surround or enclose the group of spatially distinct fusion areas.

In one example one or more of the plurality of electrically conductive contact pads distinct from the predetermined electrically conductive contact pad is mask-free. In one example at least one of the mask-free electrically conductive contact pads is coupled to a corresponding electrically conductive node of the electronic module or another electronic module mounted to the surface of the substrate panel by a corresponding intermediate solder portion, the corresponding electrically conductive node being distinct from the group of electrically conductive nodes. In one example at least one of the mask-free electrically conductive contact pads is free of any electrical coupling with the electronic module or any other electronic module mounted to the surface of the substrate panel.

In one example the electronic package further comprises a mold structure underfilling a gap between the electronic module and the surface of the substrate panel, the mold structure laterally extending between adjacent ones of the intermediate solder portions to substantially encapsulate the intermediate solder portions.

In one example the solder masking arrangement comprises a single masking element disposed over the predetermined electrically conductive contact pad.

In one example the masking arrangement comprises an arrangement of two or more masking elements disposed over the predetermined electrically conductive contact pad.

In one example each of the group of spatially distinct fusion areas is at least partially defined by corresponding openings in the masking arrangement.

In one example a periphery of at least one of the openings is closed to define perimeter.

In one example the masking arrangement defines a substantially planar outward-facing surface opposing the electronic module.

In one example the masking arrangement has a substantially uniform thickness where the masking arrangement is arranged over the predetermined electrically conductive contact pad.

In one example the group of electrically conductive nodes of the electronic module comprises a group of electrically conductive members extending away from a surface of the electronic module towards the predetermined electrically conductive contact pad, the electrically conductive members formed of an electrically conductive, non-solder material. In one example the electrically conductive, non-solder material comprises or consists of any one or more of copper, nickel, gold and or silver. In one example the electrically conductive members are cylindrical pillars.

In one example the electronic module forms part of a semiconductor die.

In one example the electronic module and/or the predetermined electrically conductive contact pad consists of or comprises a balun inductor.

In one example the electronic package is a dual-sided electronic package.

According to another embodiment there is provided an electronic assembly for use in an electronic device, the electronic assembly comprising:
a circuit board configured to receive one or more electronic packages;
an electronic package mounted to the circuit board;
the electronic package comprising:
a substrate panel,
an electronic module mounted to a surface of the substrate panel,
a plurality of electrically conductive contact pads arranged on the surface of the substrate panel;
the electronic module comprising a group of electrically conductive nodes;
a predetermined one of the plurality of electrically conductive contact pads associated with the group of electrically conductive nodes, the group of electrically conductive nodes coupled to a corresponding group of spatially distinct fusion areas of the predetermined electrically conductive contact pad by corresponding intermediate solder portions;
a solder masking arrangement extending over a part of the surface of the substrate panel, the masking arrangement arranged over the predetermined electrically conductive contact pad and configured to at least partially define the group of spatially distinct fusion areas.

According to another embodiment there is provided an electronic device comprising an electronic assembly, the electronic assembly comprising a circuit board configured to receive one or more electronic packages, an electronic package mounted to the circuit board; the electronic package including: a substrate panel, an electronic module mounted to a surface of the substrate panel, and a plurality of electrically conductive contact pads arranged on the surface of the substrate panel. The electronic module further includes a group of electrically conductive nodes. A predetermined one of the plurality of electrically conductive contact pads associated with the group of electrically conductive nodes, the group of electrically conductive nodes coupled to a corresponding group of spatially distinct fusion areas of the predetermined electrically conductive contact pad by corresponding intermediate solder portions. A solder masking arrangement extending over a part of the surface of the substrate panel, the masking arrangement arranged over the predetermined electrically conductive contact pad and configured to at least partially define the group of spatially distinct fusion areas.

In one example the electronic device is a wireless mobile device.

According to another embodiment there is provided a method of fabricating an electronic package, the method comprising steps of providing an electronic module, the electronic module comprising a group of electrically conductive nodes; providing a substrate panel, in which a plurality of electrically conductive contact pads are arranged on a surface of the substrate panel, a predetermined one of the plurality of electrically conductive contact pads associated with the group of the electrically conductive nodes; defining a solder masking arrangement extending over a part of the surface of the substrate panel to overlie the predetermined electrically conductive contact pad such that the masking arrangement at least partially defines a group of spatially distinct fusion areas of the predetermined electrically conductive contact pad, each of the group of spatially distinct fusion areas associated with a corresponding one of the group of the electrically conductive nodes; and coupling the group of electrically conductive nodes to the group of spatially distinct fusion areas by use of corresponding intermediate solder portions.

In one example the group of spatially distinct fusion areas is formed of two spatially distinct fusion areas.

In one example the step of defining a solder masking arrangement comprises configuring the masking arrangement to partially surround or enclose the group of spatially distinct fusion areas.

In one example the step of defining a solder masking arrangement comprises configuring the masking arrangement to fully surround or enclose the group of spatially distinct fusion areas.

In one example one or more of the plurality of electrically conductive contact pads distinct from the predetermined electrically conductive contact pad remain mask-free. In one example the method further comprises coupling at least one of the mask-free electrically conductive contact pads to a corresponding electrically conductive node of the electronic module or another electronic module, the corresponding electrically conductive node being distinct from the group of electrically conductive nodes. In one example at least one of the mask-free electrically conductive contact pads is free of any electrical coupling with the electronic module or any other electronic module.

In one example the step of defining a solder masking arrangement comprises applying a mask material over the predetermined electrically conductive contact pad so as to at least partially define the group of spatially distinct fusion areas.

In one example the step of defining a solder masking arrangement comprises a step of applying a mask material over the predetermined electrically conductive contact pad; and a later step of selectively removing portions of the mask material to thereby at least partially define the group of spatially distinct fusion areas.

In one example the step of defining a solder masking arrangement comprises defining the masking arrangement to comprise a single masking element disposed over the predetermined electrically conductive contact pad.

In one example the step of defining a solder masking arrangement comprises defining the masking arrangement to comprise two or more masking elements disposed over the predetermined electrically conductive contact pad.

In one example the step of defining a solder masking arrangement comprises defining a group of openings in the masking arrangement, each opening at least partially defining a corresponding one of the group of spatially distinct fusion areas.

In one example a periphery of at least one of the openings is closed to define a perimeter.

In one example the step of defining a solder masking arrangement comprises defining the masking arrangement with a substantially planar outward-facing surface opposing the electronic module.

In one example the step of defining a solder masking arrangement comprises defining the masking arrangement with a substantially uniform thickness where the masking arrangement overlies the predetermined electrically conductive contact pad.

In one example the method further comprises underfilling a gap between the electronic module and the surface of the substrate panel with a mold material to define a mold structure laterally extending between adjacent ones of the intermediate solder portions to substantially encapsulate the intermediate solder portions.

In one example the electronic module is provided with a group of electrically conductive members extending away from a surface of the electronic module, the electrically conductive members formed of an electrically conductive, non-solder material, each of the group of electrically conductive members defining corresponding ones of the group of electrically conductive nodes of the electronic module. In one example the electrically conductive, non-solder material comprises or consists of any one or more of copper, nickel, gold and or silver. In one example the electrically conductive members are formed as cylindrical pillars.

In one example the electronic module forms part of a semiconductor die.

In one example the electronic module and/or the predetermined electrically conductive contact pad consists of or comprises a balun inductor.

According to another embodiment there is provided a method of fabricating an electronic assembly for use in an electronic device, comprising fabricating an electronic package by steps of: providing an electronic module, the electronic module comprising a group of electrically conductive nodes; providing a substrate panel, in which a plurality of electrically conductive contact pads are arranged on a surface of the substrate panel, a predetermined one of the plurality of electrically conductive contact pads associated with the group of the electrically conductive nodes; defining a solder masking arrangement extending over a part of the surface of the substrate panel to overlie the predetermined electrically conductive contact pad such that the masking arrangement at least partially defines a group of spatially distinct fusion areas of the predetermined electrically conductive contact pad, each of the group of spatially distinct fusion areas associated with a corresponding one of the group of the electrically conductive nodes; coupling the group of electrically conductive nodes to the group of spatially distinct fusion areas by use of corresponding intermediate solder portions. The method further comprises mounting the electronic package to a circuit board to form the electronic assembly.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment”, “some embodiments”, “an alternate embodiment”, “various embodiments”, “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic plan view of a portion of a surface of a substrate panel according to the background art, showing a contact pad arranged on the surface of the substrate panel.

FIG. 2 is a schematic cross-sectional view of a portion of an electronic package according to the background art, in which an electronic module of a semiconductor die is coupled to the contact pad via intermediate portions of solder.

FIG. 3 is a schematic view of section A-A of FIG. 2, showing lateral spread of the intermediate portions of solder over the surface of the contact pad.

FIG. 4A is a schematic plan view of a portion of a surface of a substrate panel according to aspects of the present disclosure, showing a masked contact pad arranged on the surface of the substrate panel and various mask-free contact pads also arranged on the surface of the substrate panel.

FIG. 4B is a schematic plan view of an alternative embodiment to that of FIG. 4A.

FIG. 4C is a schematic plan view of a further alternative embodiment to that of FIG. 4A.

FIG. 4D is a schematic plan view of a further alternative embodiment to that of FIG. 4A.

FIG. 5 is a schematic perspective view of the portion of the substrate panel of FIG. 4A.

FIG. 6 is a schematic cross-sectional view of a portion of an electronic package according to aspects of the present disclosure, taken along a part of section B-B corresponding to Region A of FIG. 5, in which a semiconductor die is positioned over the surface of the substrate panel and intermediate portions of solder are positioned between an electronic module of the die and the masked contact pad.

FIG. 7 is a schematic cross-sectional view of the portion of the electronic package of FIG. 6, but showing the package after a reflow soldering operation has been performed to fuse the intermediate portions of solder to spatially distinct fusion areas of the masked contact pad.

FIG. 8A is an expanded view of the electronic package of FIG. 7, illustrating a larger proportion of the electronic package (corresponding to all of section B-B of FIG. 5), with a solder portion coupling one of the mask-free contact pads to another electronic module of the semiconductor die.

FIG. 8B illustrates an alternative embodiment to the electronic package of FIG. 8A, differing in that the illustrated mask-free contact pad is free of any solder portion.

FIG. 9 is a schematic cross-sectional view of the entirety of the electronic package for the embodiment of FIGS. 4A, 5, 6, 7 and 8A.

FIG. 10 is a schematic cross-sectional view showing the electronic package of FIG. 9 when mounted to a circuit board to form an electronic assembly.

FIG. 11 is a representation of various steps of a method of fabricating an electronic package according to aspects of the present disclosure.

FIG. 12 illustrates an electronic package implemented in a wireless device, according to aspects of the present disclosure.

### DETAILED DESCRIPTION

Aspects and embodiments described herein are directed to an electronic package, preferably a dual-sided electronic package, in which an electronic module is coupled to a substrate panel of the electronic package using intermediate portions of solder. In particular, aspects and embodiments described herein provide for coupling a group of electrically conductive nodes of an electronic module to a common electrically conductive contact pad arranged on a surface of a substrate panel by use of intermediate portions of solder. Aspects and embodiments described herein may inhibit lateral spread and amalgamation of adjacent intermediate solder portions over the common contact pad. Aspects and embodiments described herein are also directed to an electronic assembly including such an electronic package, an electronic device including such an electronic assembly, as well as the manufacture of such an electronic package.

It is to be appreciated that embodiments of the packages, assemblies, devices and methods discussed herein are not limited in application to the details of construction and the arrangement of components set forth in the following description or illustrated in the accompanying drawings. The packages, assemblies, devices and methods are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including”, “comprising”, “having”, “containing”, “involving”, and variations thereof is meant to encompass the items listed thereafter and equivalents thereof as well as additional items. References to “or” may be construed as inclusive so that any terms described using “or” may indicate any of a single, more than one, and all of the described terms.

### Electronic Package of the Background Art:

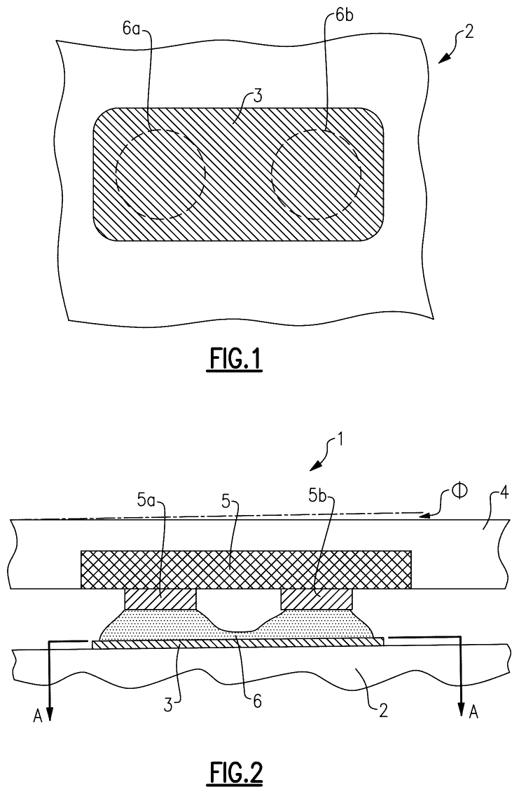

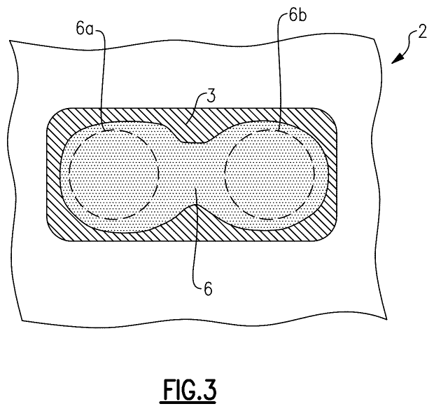

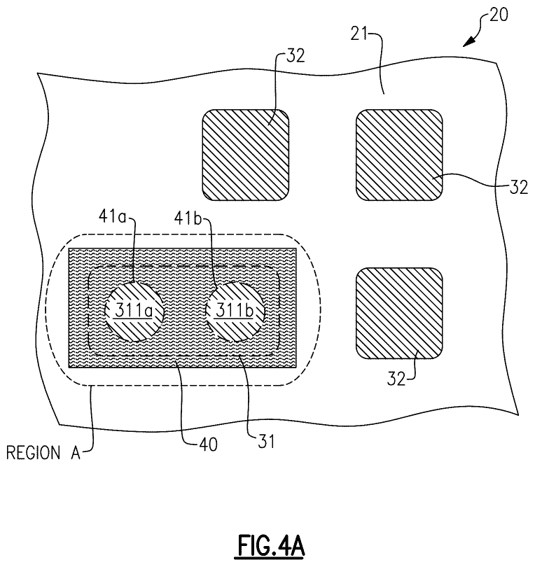

FIG. 1 is a schematic plan view of a portion of a surface of a substrate panel 2 according to the background art. An electrically conductive contact pad 3 is arranged on the surface of the substrate panel 2. As shown in FIG. 2, an electronic module 5 of a semiconductor die 4 is coupled to the contact pad 3 by two intermediate portions of solder 6a, 6b to form an electronic package 1. It will be appreciated that only a minor portion of the electronic package 1 is shown in FIG. 2. The electronic module 5 has a configuration in which optimum or efficient operation of the module is facilitated by having two or more electrically conductive nodes of the module being electrically coupled to a common electrical interface on the substrate panel 2. More specifically, for the example shown in FIG. 2, two electrically conductive nodes 5a, 5b of the electronic module 5 are coupled to distinct areas of the contact pad 3 by the two intermediate portions of solder 6a, 6b. Solder portion 6a is intended to extend between electrically conductive node 5a and a first respective area of contact pad 3. Solder portion 6b is intended to extend between electrically conductive node 5b and a second respective area of contact pad 3. The intended maximum contact area between the intermediate portions of solder 6a, 6b and the contact pad 3 after reflow of the solder portions is shown in FIGS. 1 and 3 by two dashed circular outlines.

The application of heat to reflow and fuse the solder portions 6a, 6b to the contact pad 3 and the respective electrically conductive nodes 5a, 5b can result in lateral spread of the solder over the surface of the contact pad. If the lateral spread is sufficient, the discrete portions of solder 6a, 6b may amalgamate to form a unified body 6 of solder, as illustrated in FIGS. 2 and 3. Where the lateral spread is non-uniform between the different solder portions 6a, 6b, the height of one solder portion may differ from the height of the other solder portion, resulting in the semiconductor die 4 becoming misaligned so as to be non-parallel relative to the substrate panel 2. This phenomenon is known as “die tilt” and is illustrated in FIG. 2, with angle Φ representing the deviation of the semiconductor die 5 from a parallel alignment with the substrate panel 2. Other undesired consequences of lateral spread of the solder portions 6a, 6b can include a reduced contact area between one or both of the solder portions 6a, 6b and the respective electrically conductive nodes 5a, 5b of the electronic module 5. In extreme cases, the lateral spread of the solder may be such that a gap is present between one of the solder portions 6a, 6b and the respective electrically conductive node 5a, 5b.

Known alternatives to coupling the electrically conductive nodes 5a, 5b to a common contact pad 3 include coupling the electrically conductive nodes to distinct contact pads, but providing routing through one or more layers within the substrate panel 2 electrically coupling the distinct contact pads to each other. However, these alternatives can impact the performance of the electronic module 5 and the semiconductor die 4 of which it forms part.

### Electronic Package According to Aspects of the Present Disclosure:

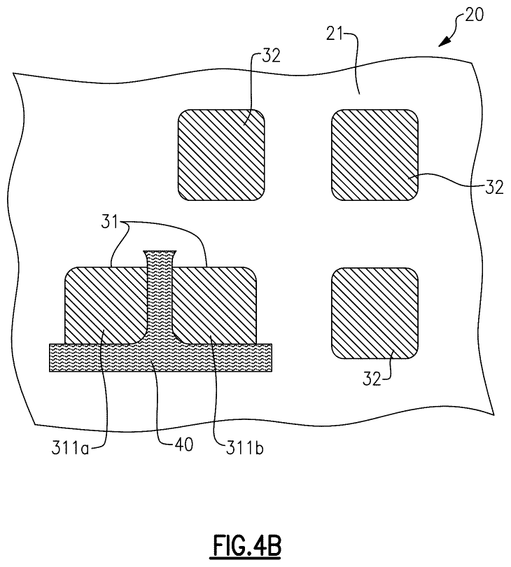

FIG. 4A shows a plan view of a first surface 21 of a substrate panel 20 according to aspects of the present disclosure. The substrate panel 2 is generally planar in form. The substrate panel 2 may have a laminate construction. The substrate panel 2 may include a ceramic substrate. The ceramic substrate may include a low temperature co-fired ceramic substrate. However, it will be appreciated that other materials may be used to form the substrate panel 2.

A contact pad 31 is arranged on the first surface 21 of the substrate panel 20. Three other contact pads 32 are also arranged on the first surface 21 of the substrate panel 20. The contact pads 31, 32 are electrically conductive. The contact pads 31, 32 may be formed of or include copper. However, it will be appreciated that the contact pads 31, 32 may be formed of or include other electrically conductive materials. The contact pad 31 is indicated as being larger in surface area than the other contact pads 32. The contact pads 31, 32 may be referred to as substrate pad formations.

A solder masking arrangement 40 extends over a part of the first surface 21 of the substrate panel 20 and overlies the contact pad 31. FIG. 4A shows the masking arrangement localised to the contact pad 31. However, in other embodiments the masking arrangement 41 may extend to cover a greater extent of the first surface 21 of the substrate panel 20. The masking arrangement 40 may be formed of a layer of an epoxy-based material. However, it will be appreciated that other materials may be used to form the masking arrangement 40. The masking arrangement 40 may be formed from an electrically insulative material.

Two circular openings 41a, 41b are provided in the masking arrangement 40. The openings 41a, 41b define a group of spatially distinct fusion areas 311a, 311b of contact pad 31. The perimeter of the circular openings 41a, 41b fully surrounds and encloses the spatially distinct fusion areas 311, 311b. The other contact pads 32 and much of the first surface 21 of the substrate panel 20 away from the contact pad 31 are free of any masking material. The outline of the contact pad 31 underlying the masking arrangement 40 is indicated by a dashed line in FIG. 4A. It will be appreciated that in other embodiments, the openings may define a closed shape other than a circle.

FIG. 4B illustrates an alternative embodiment to that of FIG. 4A. In the embodiment of FIG. 4B, the masking arrangement 40 does not include any closed opening. Instead, a portion of the masking arrangement 40 overlies a mid-region of the contact pad 31 to separate the contact pad into spatially distinct fusion areas 311a, 311b. Another portion of the masking arrangement 40 extends along one side of the length of the contact pad 31. In contrast to the embodiment of FIG. 4A, the masking arrangement 40 only partially surrounds or encloses each fusion area 311a, 311b.

FIG. 4C illustrates a further alternative embodiment to that of FIG. 4A. In the embodiment of FIG. 4C, the masking arrangement 40 does not include any closed opening. Instead, the masking arrangement 40 overlies only a mid-region of the contact pad 31 to separate the contact pad into spatially distinct fusion areas 311a, 311b. In common with the embodiment of FIG. 4B, the masking arrangement 40 only partially surrounds or encloses each fusion area 311a, 311b.

FIG. 4D illustrates a further alternative embodiment to that of FIG. 4A. In the embodiment of FIG. 4D, the masking arrangement 40 does not include any closed opening. Instead, the masking arrangement 40 has three masking elements 40a, 40b, 40c. Masking element 40a overlies a mid-region of the contact pad 31, with masking elements 40b and 40c located to overlie opposite ends of the contact pad. Fusion area 311a is partially defined by the separation between masking elements 40a and 40b, with masking elements 40a, 40b only partially surrounding or enclosing the fusion area 311a. Fusion area 311b is partially defined by the separation between masking elements 40a and 40c, with masking elements 40a, 40c only partially surrounding or enclosing the fusion area 311b.

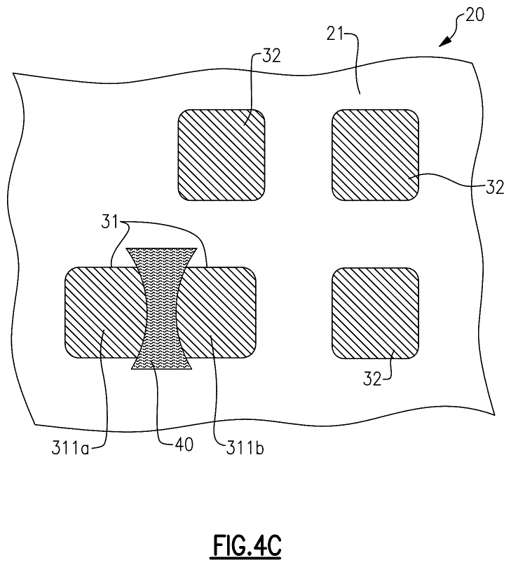

FIG. 5 is a schematic perspective view of portion of the substrate panel 20 of FIG. 4A. As shown in FIG. 5, the openings 41a, 41b in the masking arrangement 40 extend for a depth ‘d’ down to a surface of the contact pad 31.

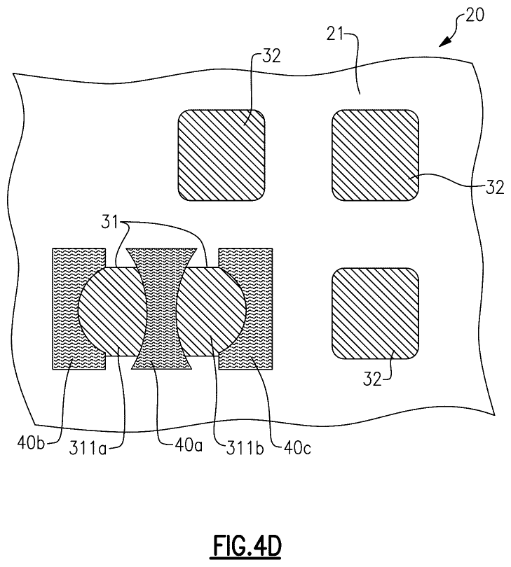

FIG. 6 is a schematic cross-sectional view taken along a part of section B-B of FIG. 5, but additionally including a portion of a semiconductor die 50 positioned over the first surface 21 of the substrate panel 20 to form electronic package 10. The semiconductor die 50 incorporates an electronic module 51. The electronic module 51 may be a balun inductor. However, it will be appreciated that the electronic module 51 may be any form of electronic module in which optimum or efficient operation is facilitated by having two or more electrically conductive nodes of the electronic module coupled to a common electrical interface on the substrate panel 20. As shown in FIG. 6, the electronic module 51 has a group of two electrically conductive nodes 511a, 511b protruding from an underside of the die 50. The electrically conductive nodes 511a, 511b define electrical inputs or outputs of the electronic module 51. The electrically conductive nodes 511a, 511b illustrated in FIG. 6 comprise electrically conductive members in the form of copper pillars. The copper pillars may be integrally formed with the underside of the electronic module 51, or be separately fused to the underside of the electronic module 51. It will be appreciated that the electrically conductive members may have any other suitable geometric profile and/or be formed of electrically conductive materials other than copper, such as nickel, gold or silver.

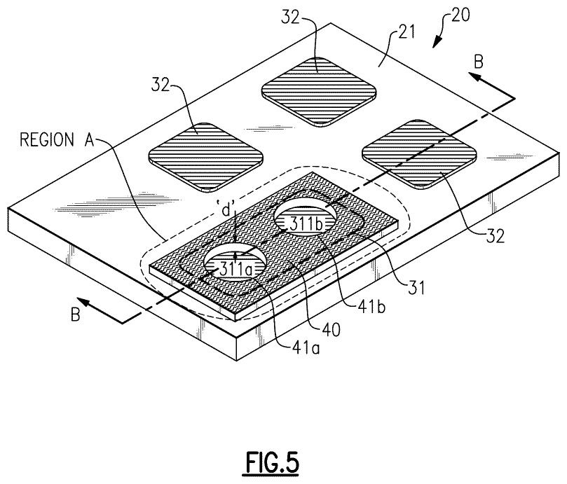

The contact pad 31 is associated with the group of two electrically conductive nodes 511a, 511b of the electronic module 51. More specifically, as shown in FIG. 6, two intermediate portions of solder 60a, 60b are positioned between the group of electrically conductive nodes 511a, 511b of the electronic module 51 and the group of spatially distinct fusion areas 311a, 311b of the contact pad 31. A reflow soldering operation is then performed to apply sufficient heat to reflow and fuse the solder portions 60a, 60b to the respective electrically conductive nodes 511a, 511b and fusion areas 311a, 311b. FIG. 6 shows the initial location and shape of the intermediate solder portions 60a, 60b prior to the application of any heat to the solder. On completion of the reflow soldering operation, the solder portions 60a, 60b have the profile indicated in FIG. 7.

As shown in FIG. 7, the depth of the openings 41a, 41b in the masking arrangement 40 facilitates limiting lateral spread of the material of the solder portions 60a, 60b during the reflow soldering operation. More specifically, FIG. 7 shows the reflowed solder portions 60a, 60b remaining spatially distinct from each other. Each of the reflowed solder portions 60a, 60b has a uniform height, with the semiconductor die 50 remaining aligned parallel to the first surface 21 of the substrate panel 20. Once the reflowed solder portions 60a, 60b have cooled to ambient temperature, mold material is injected into the gap between the underside of the semiconductor die 50 and the first surface 21 of the substrate panel 20 to underfill the gap and form mold structure 70 (see FIG. 7). The mold material of the mold structure 70 is optionally formed from an epoxy material. However, it will be appreciated that other materials may instead be used to form the mold structure 70. The mold structure 70 laterally extends between adjacent ones of the solder portions 60a, 60b to substantially encapsulate the solder portions.

Having the masking arrangement 40 extending over only part of the first surface 21 of the substrate panel 20 avoids locally reducing the gap between the contact pad 32 and the semiconductor die 50, thereby avoiding a potential obstruction to mold flow when injecting the mold material to form mold structure 70.

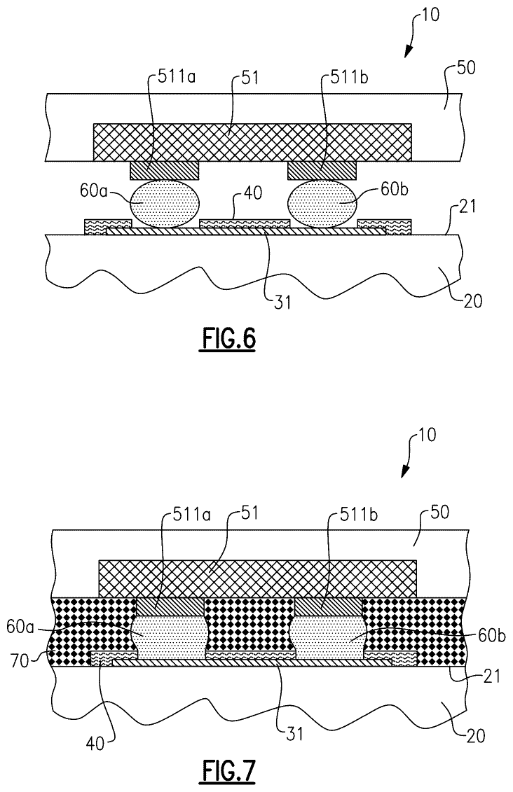

FIG. 8A shows a larger portion of the electronic package 10 relative to that illustrated in FIG. 7, plus the mask-free contact pad 32 in section B-B of FIG. 5. As shown in FIG. 8A, the semiconductor die 50 also includes a second electronic module 52. An intermediate solder portion 62 fuses an electrically conductive node 521 of the electronic module 52 to the mask-free contact pad 32.

FIG. 8B illustrates an alternative embodiment of electronic package 10′ to that illustrated in FIG. 8A, differing in that there is no electrical coupling extending between the mask-free contact pad 32 and the semiconductor die 50/second electronic module 52.

The lack of a solder mask on the contact pads 32 avoids locally reducing the gap between the contact pad 32 and the semiconductor die 50, thereby avoiding a potential obstruction to mold flow when injecting the mold material to form mold structure 70.

Some or all of the mask-free contact pads 32 may be coupled to the semiconductor die 50 or electronic modules of the die by intermediate solder portions, in a similar manner to that shown in FIG. 8A. Similarly, some or all of the mask-free contact pads 32 may be free of any such intermediate solder portions, in a similar manner to that shown in FIG. 8B.

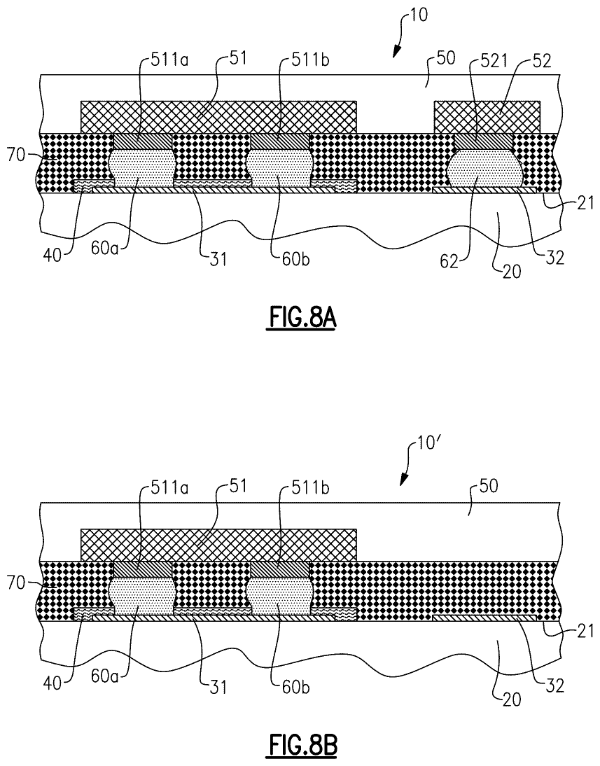

FIG. 9 shows a view of the electronic package 10 corresponding to the embodiment of FIGS. 4A, 5, 6, 7 and 8A. The embodiment of FIG. 9 shows the intermediate solder portions 60a, 60b, 62 mounting the semiconductor die 50 to the first surface 21 of the substrate panel 20. However, it will be appreciated that in other embodiments an annular array of through-mold connections may additionally be provided to assist in mounting the semiconductor die 50 to the first surface 21 of the substrate panel 20, the annular array being positioned slightly inboard of the perimeter of the semiconductor die 50. By way of example, such through-mold connections may be in the form of solder portions fused to corresponding interfaces of the semiconductor die 50 and the substrate panel 20.

For the embodiment of FIG. 9, a flip chip 53 is mounted to a second surface 22 of the substrate panel 20. The second surface 22 is located on an opposite side of the substrate panel 20 from the first surface 21. An annular array of through-mold connections 65 is positioned on respective contact pads 35 arranged on the second surface 22 of the substrate panel 20 to surround the flip chip 53. In common with contact pads 31, 32, the contact pads 35 are formed of copper. In the example shown, the through-mold connections 65 are formed of a solder material. A mold structure 71 overlies the second surface 22 and substantially encapsulates the annular array of through-mold connections 65 and the flip chip 53, but with exposed surfaces of the through-mold connections 65 being flush with an outer surface of the mold structure 71. The mold structure 71 may be formed from the same material used for mold structure 70. It will be appreciated that the semiconductor die 50 may incorporate additional electronic modules to electronic modules 51, 52. It will also be appreciated that in addition to semiconductor die 50, one or more other electronic modules may also be coupled to the first surface 21 of the substrate panel 20. It will also be appreciated that the electronic module 51 may be coupled to the first surface 21 of the substrate panel 20 without being integrated as part of any semiconductor die 50. Similarly, it will be appreciated that one or more other electronic modules may be used in addition to or in place of the flip chip 53 on the second surface 22 of the substrate panel 20.

The mold structures 70 and 71 may help to protect the various electronic modules 51, 52, 53 mounted to the opposing surfaces 21, 22 of the substrate panel 20 from impact loads encountered during validation testing, transportation or operational use. Impact loads may be dissipated throughout the mold structures 70, 71, thereby helping to reduce the forces encountered by components of the electronic package. In other embodiments, a mold structure may also be overlaid over the first surface 21 of the substrate panel 20 so as to substantially encapsulate the whole of semiconductor die 50.

The electronic package 100 illustrated in FIG. 9 may be referred to as a dual-sided (DS) package, by virtue of electronic modules being mounted to opposing surfaces 21, 22 of the substrate panel 20.

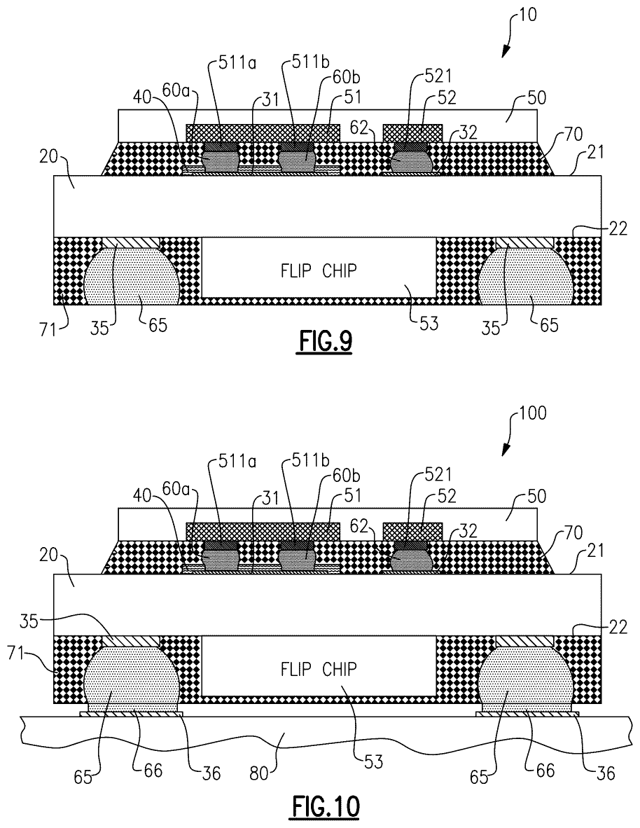

As shown in FIG. 10, the electronic package 10 of FIG. 9 may subsequently be mounted to a circuit board 80 to form an electronic assembly 100. The electronic package 10 is mounted to circuit board 80 by use of intermediate portions of solder 66 extending between exposed surfaces of the through-mold connections 65 and corresponding mounting locations (in the form of electrically conductive contact pads 36) provided on the circuit board 80. The circuit board 80 may itself form part of an electronic device, such as a wireless device. By way of example and without limitation, the wireless device may take the form of a mobile phone, a tablet computer, a smart watch and a laptop computer.

### Methods for Manufacturing Electronic Packages According to Aspects of the Present Disclosure:

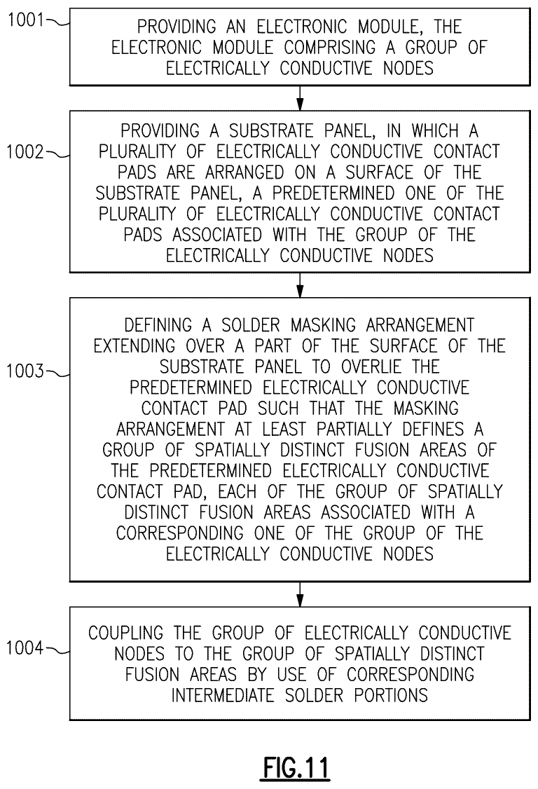

FIG. 11 illustrates steps of a method of fabricating an electronic package, such as the electronic package 10, 10′ described in the preceding paragraphs.

In step 1001, an electronic module is provided. The electronic module has a group of electrically conductive nodes. The electronic module may be in the form of electronic module 51 having the group of electrically conductive nodes 511a, 511b, as described above in relation to FIGS. 4A to 10. The electronic module may be a balun inductor or any other electronic module in which optimum or efficient operation is facilitated by having two or more electrically conductive nodes of the electronic module coupled to a common electrical interface on a substrate panel.

In step 1002, a substrate panel is provided, in which a plurality of electrically conductive contact pads are arranged on a surface of the substrate panel. A predetermined one of the plurality of electrically conductive contact pads is associated with the group of the electrically conductive nodes. The substrate panel may take the form of substrate panel 20, with contact pads 31, 32 arranged on first surface 21 of the substrate panel, as described above in relation to FIGS. 4A to 10. The predetermined contact pad may take the form of contact pad 31, as described above in relation to FIGS. 4A to 10.

In step 1003, a solder masking arrangement is defined extending over a part of the surface of the substrate panel to overlie the predetermined electrically conductive contact pad such that the masking arrangement at least partially defines a group of spatially distinct fusion areas of the predetermined electrically conductive contact pad. Each of the group of spatially distinct fusion areas is associated with a corresponding one of the group of the electrically conductive nodes. The solder masking arrangement and spatially distinct fusion areas may take the form of the masking arrangement 40 and fusion areas 311a, 311b, as discussed above in relation to FIGS. 4A to 10. As previously described, the masking arrangement may be formed of an epoxy material. However, as previously discussed, it will be appreciated that alternative materials may be used for the masking arrangement. The masking arrangement may be formed from an electrically insulative material. The mask material may be applied by photolithography to form the masking arrangement. The mask material may be applied by a screen-printing technique to avoid mask material being overlaid on the spatially distinct fusion areas of the predetermine contact pad. Alternatively, the mask material may initially be applied to overlie substantially all of the predetermined contact pad, with a later step performed of selectively removing portions of the mask material to expose and at least partially define the group of spatially distinct fusion areas.

In step 1004, the group of electrically conductive nodes are coupled to the group of spatially distinct fusion areas by use of corresponding intermediate solder portions. The intermediate solder portions may correspond to the intermediate solder portions 60a, 60b as discussed in relation to FIGS. 4 to 10.

Steps 1001 to 1004 result in the fabrication of an electronic package, such as the electronic packages 10, 10′ discussed above in relation to FIGS. 4A to 10. The electronic package resulting from the described method may subsequently be mounted to a circuit board, as will be understood from discussion of FIGS. 4A to 10. The electronic assembly may form part of an electronic device, such as a wireless device. As described above, the wireless device may take the form of a mobile phone, a tablet computer, a smart watch and a laptop computer.

### Exemplary Devices Incorporating Electronic Package According to Aspects of the Present Disclosure:

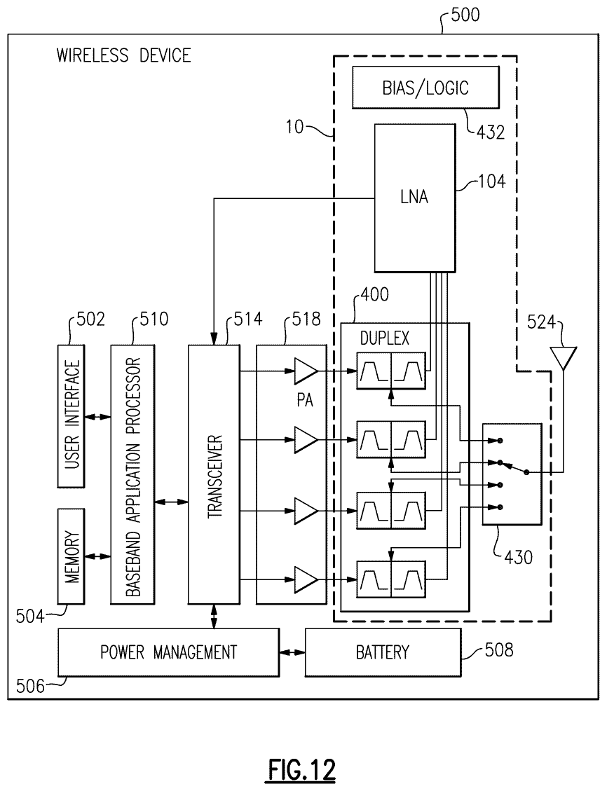

FIG. 12 illustrates an example of how a dual-sided electronic package 10 may be implanted in an electronic device, such as wireless device 500. In the example wireless device 500 of FIG. 12, the electronic package 10 may be an LNA or LNA-related module-represented by the dashed outline in FIG. 18. By way of example, the LNA module 10 may include one or more LNA's 104, a bias/logic circuit 432, and a band-selection switch 430. Some or all of such circuits can be implemented in a semiconductor die that is mounted on a substrate panel 20 of the LNA module 10. In such an LNA module, some or all of duplexers 400 can be mounted on the substrate panel 20 so as to form a dual-sided package having one or more features as described herein.

FIG. 12 further depicts various features associated with the example wireless device 500. Although not specifically shown in FIG. 12, the electronic package 10 may instead take the form of a diversity receive (RX) module in place of the LNA module. Alternatively, the electronic package 10 may take the form of a combination of a diversity RX module and an LNA module. It will also be understood that a dual-sided package 10 having one or more features as described herein can be implemented in the wireless device 500 as a non-LNA module.

In the example wireless device 500, a power amplifier (PA) circuit 518 having a plurality of PA's can provide an amplified RF signal to switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

The transceiver 514 is shown to interact with a baseband subsystem 510 that is configured to provide conversion between data and/or voice signals suitable for a user and RF signals suitable for the transceiver 514. The transceiver 514 is also shown to be connected to a power management component 506 that is configured to manage power for the operation of the wireless device 500. Such a power management component can also control operations of the baseband sub-system 510.

The baseband sub-system 510 is shown to be connected to a user interface 502 to facilitate various input and output of voice and/or data provided to and received from the user. The baseband sub-system 510 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

It will be noted that the figures are for illustrative purposes only, and are not to scale.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. An electronic package comprising:
a substrate panel;
an electronic module mounted to a surface of the substrate panel and including a group of electrically conductive nodes;
a plurality of electrically conductive contact pads arranged on the surface of the substrate panel, a predetermined one of the plurality of electrically conductive contact pads is associated with the group of electrically conductive nodes, the group of electrically conductive nodes coupled to a corresponding group of spatially distinct fusion areas of the predetermined electrically conductive contact pad by corresponding intermediate solder portions; and
a solder masking arrangement extending over a part of the surface of the substrate panel, the masking arrangement arranged over the predetermined electrically conductive contact pad and configured to at least partially define the group of spatially distinct fusion areas.

2. The electronic package of claim 1 in which the group of spatially distinct fusion areas is formed of two spatially distinct fusion areas.

3. The electronic package of claim 1 in which the masking arrangement is configured to partially surround or enclose the group of spatially distinct fusion areas.

4. The electronic package of claim 1 in which the masking arrangement is configured to fully surround or enclose the group of spatially distinct fusion areas.

5. The electronic package of claim 1 in which one or more of the plurality of electrically conductive contact pads distinct from the predetermined electrically conductive contact pad is mask-free.

6. The electronic package of claim 5 in which at least one of the mask-free electrically conductive contact pads is coupled to a corresponding electrically conductive node of the electronic module or another electronic module mounted to the surface of the substrate panel by a corresponding intermediate solder portion, the corresponding electrically conductive node being distinct from the group of electrically conductive nodes.

7. The electronic package of claim 5 in which at least one of the mask-free electrically conductive contact pads is free of any electrical coupling with the electronic module or any other electronic module mounted to the surface of the substrate panel.

8. The electronic package of claim 1 further comprising a mold structure underfilling a gap between the electronic module and the surface of the substrate panel, the mold structure laterally extending between adjacent ones of the intermediate solder portions to substantially encapsulate the intermediate solder portions.

9. The electronic package of claim 1 in which the solder masking arrangement includes a single masking element disposed over the predetermined electrically conductive contact pad.

10. The electronic package of claim 1 in which the masking arrangement includes an arrangement of two or more masking elements disposed over the predetermined electrically conductive contact pad.

11. The electronic package of claim 1 in which each of the group of spatially distinct fusion areas is at least partially defined by corresponding openings in the masking arrangement.

12. The electronic package of claim 11 in which a periphery of at least one of the openings is closed to define a perimeter.

13. The electronic package of claim 1 in which the masking arrangement defines a substantially planar outward-facing surface opposing the electronic module.

14. The electronic package of claim 1 in which the masking arrangement has a substantially uniform thickness where the masking arrangement is arranged over the predetermined electrically conductive contact pad.

15. The electronic package of claim 1 in which the group of electrically conductive nodes of the electronic module includes a group of electrically conductive members extending away from a surface of the electronic module towards the predetermined electrically conductive contact pad, the electrically conductive members formed of an electrically conductive, non-solder material.

16. The electronic package of claim 15 in which the electrically conductive, non-solder material includes or consists of any one or more of copper, nickel, gold and or silver.

17. The electronic package of claim 15 in which the electrically conductive members are cylindrical pillars.

18. The electronic package of claim 1 in which the electronic module forms part of a semiconductor die.

19. An electronic assembly for used in an electronic device, the electronic assembly comprising:
a circuit board configured to receive one or more electronic packages;
an electronic package mounted to the circuit board, the electronic package including a substrate panel, an electronic module mounted to a surface of the substrate panel, and a plurality of electrically conductive contact pads arranged on the surface of the substrate panel, the electronic module including a group of electrically conductive nodes, a predetermined one of the plurality of electrically conductive contact pads associated with the group of electrically conductive nodes, the group of electrically conductive nodes coupled to a corresponding group of spatially distinct fusion areas of the predetermined electrically conductive contact pad by corresponding intermediate solder portions, and the electronic package further including a solder masking arrangement extending over a part of the surface of the substrate panel, the masking arrangement arranged over the predetermined electrically conductive contact pad and configured to at least partially define the group of spatially distinct fusion areas.

20. An wireless device comprising:
an electronic assembly including a circuit board configured to receive one or more electronic packages, the electronic assembly further including an electronic package mounted to the circuit board and including a substrate panel, an electronic module mounted to a surface of the substrate panel, a plurality of electrically conductive contact pads arranged on the surface of the substrate panel, the electronic module including a group of electrically conductive nodes, a predetermined one of the plurality of electrically conductive contact pads associated with the group of electrically conductive nodes, the group of electrically conductive nodes coupled to a corresponding group of spatially distinct fusion areas of the predetermined electrically conductive contact pad by corresponding intermediate solder portions, and the electronic package further including a solder masking arrangement extending over a part of the surface of the substrate panel, the masking arrangement arranged over the predetermined electrically conductive contact pad and configured to at least partially define the group of spatially distinct fusion areas.
